(19) United States
(12) Patent Application Publication
(10) Pub. No.: US 2024/0282579 A1
(43) Pub. Date: Aug. 22, 2024

(54) MANUFACTURING METHOD OF SEMICONDUCTOR STRUCTURE

(71) Applicant: Powerchip Semiconductor Manufacturing Corporation, Hsinchu (TW)

(72) Inventors: Mao-Teng Hsu, Hsinchu County (TW); Shih-Ping Lee, Hsinchu City (TW); Kuo-Tung Peng, Hsinchu County (TW)

(73) Assignee: Powerchip Semiconductor Manufacturing Corporation, Hsinchu (TW)

(21) Appl. No.: 18/306,253

(22) Filed: Apr. 25, 2023

(30) Foreign Application Priority Data
Feb. 20, 2023 (TW) 112106101

(51) Int. Cl. H01L 21/266; H01L 21/02; H01L 21/265; H01L 21/324

(52) U.S. Cl. CPC H01L 21/266; H01L 21/02238; H01L 21/26513; H01L 21/324

(57) ABSTRACT

The invention provides a manufacturing method of a semiconductor structure, which includes the following. A substrate is provided. The substrate includes a region of a first conductivity type. A patterned photoresist layer is formed on the substrate. The patterned photoresist layer includes a main portion and a split portion separated from each other. An ion implantation process is performed on the substrate by using the patterned photoresist layer as a mask to form a well region in the region of the first conductivity type. The well region has a second conductivity type. The main portion and the split portion are adjacent to the same end terminal of the well region.

### CROSS-REFERENCE TO RELATED APPLICATION

This application claims the priority benefit of Taiwan application serial no. 112106101, filed on Feb. 20, 2023. The entirety of the above-mentioned patent application is hereby incorporated by reference herein and made a part of this specification.

### BACKGROUND

### Technical Field

The disclosure relates to a manufacturing method of a semiconductor structure, and in particular to a manufacturing method of a semiconductor structure capable of increasing the breakdown voltage of a PN junction.

### Description of Related Art

In some semiconductor structures, there are P-type regions and N-type regions in the substrate, and there is a PN junction between the P-type regions and the N-type regions. However, how to increase the breakdown voltage of the PN junction is an ongoing goal.

### SUMMARY

The disclosure provides a manufacturing method of a semiconductor structure, which can increase a breakdown voltage of a PN junction.

The disclosure provides the manufacturing method of the semiconductor structure, which includes the following. A substrate is provided. The substrate includes a region of a first conductivity type. A patterned photoresist layer is formed above the substrate. The patterned photoresist layer includes a main portion and a split portion separated from each other. An ion implantation process is performed on the substrate by using the patterned photoresist layer as a mask to form a well region in the region of the first conductivity type. The well region has a second conductivity type. The main portion and the split portion are adjacent to the same end terminal of the well region.

According to an embodiment of the disclosure, in the manufacturing method of the semiconductor structure, the first conductivity type may be a P-type conductivity type, and the second conductivity type may be an N-type conductivity type.

According to an embodiment of the disclosure, in the manufacturing method of the semiconductor structure, the first conductivity type may be the N-type conductivity type, and the second conductivity type may be the P-type conductivity type.

According to an embodiment of the disclosure, in the manufacturing method of the semiconductor structure, the split portion may be a terminal portion of the patterned photoresist layer.

According to an embodiment of the disclosure, in the manufacturing method of the semiconductor structure, the split portion may be positioned directly above the well region.

According to an embodiment of the disclosure, in the manufacturing method of the semiconductor structure, a width of the main portion may be greater than a width of the split portion.

According to an embodiment of the disclosure, in the manufacturing method of the semiconductor structure, the width of the split portion may be 0.05 μm to 2 μm.

According to an embodiment of the disclosure, in the manufacturing method of the semiconductor structure, the width of the split portion may be 0.2 μm to 1 μm.

According to an embodiment of the disclosure, in the manufacturing method of the semiconductor structure, a spacing of the main portion and the split portion may be 0.05 μm to 2 μm.

According to an embodiment of the disclosure, in the manufacturing method of the semiconductor structure, the spacing of the main portion and the split portion may be 0.2 μm to 1 μm.

According to an embodiment of the disclosure, the manufacturing method of the semiconductor structure may further include the following. The patterned photoresist layer is removed. A heating process is performed on the substrate.

According to an embodiment of the disclosure, in the manufacturing method of the semiconductor structure, the heating process is, for example, an anneal process.

According to an embodiment of the disclosure, the manufacturing method of the semiconductor structure may further include the following. A dielectric layer is formed on the substrate.

According to an embodiment of the disclosure, in the manufacturing method of the semiconductor structure, a part of the patterned photoresist layer may be positioned on the dielectric layer.

According to an embodiment of the disclosure, in the manufacturing method of the semiconductor structure, the patterned photoresist layer may expose a part of the dielectric layer.

According to an embodiment of the disclosure, in the manufacturing method of the semiconductor structure, a forming method of the dielectric layer is, for example, a thermal oxidation method.

According to an embodiment of the disclosure, the manufacturing method of the semiconductor structure may further include the following. An isolation structure is formed in the substrate.

According to an embodiment of the disclosure, in the manufacturing method of the semiconductor structure, a part of the patterned photoresist layer may be positioned on the isolation structure.

According to an embodiment of the disclosure, in the manufacturing method of the semiconductor structure, the patterned photoresist layer may expose a part of the isolation structure.

According to an embodiment of the disclosure, in the manufacturing method of the semiconductor structure, a part of the well region may be positioned directly under the isolation structure.

Based on the above, in the manufacturing method of the semiconductor structure provided by the disclosure, the patterned photoresist layer is formed above the substrate, and the patterned photoresist layer includes the main portion and the split portion separated from each other. Next, the ion implantation process is performed on the substrate by using the patterned photoresist layer as a mask to form the well region of the second conductivity type in the region of the first conductivity type. In this way, a part of the well region adjacent to the end terminal may have a low doping concentration, so that a depletion region may be enlarged, thereby increasing the breakdown voltage of the PN junction.

In order to make the above-mentioned features and advantages of the disclosure more comprehensible, several embodiments accompanied with drawings are described in detail as follows.

### BRIEF DESCRIPTION OF THE DRAWINGS

FIG. 1A to FIG. 1C are cross-sectional views of a manufacturing process of a semiconductor structure according to some embodiments of the disclosure.

### DESCRIPTION OF THE EMBODIMENTS

Embodiments are listed below and described in detail with accompanying drawings, but the provided embodiments are not intended to limit the scope of the disclosure. In order to facilitate understanding, the same components will be described with the same reference numerals in the following description. In addition, the drawings are for illustration purposes only and are not drawn to original scale. In fact, the dimensions of the various features may be arbitrarily increased or reduced for clarity of discussion.

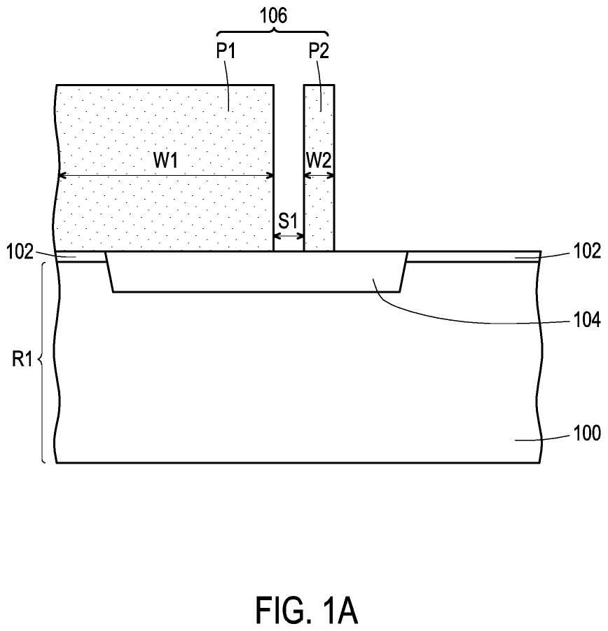

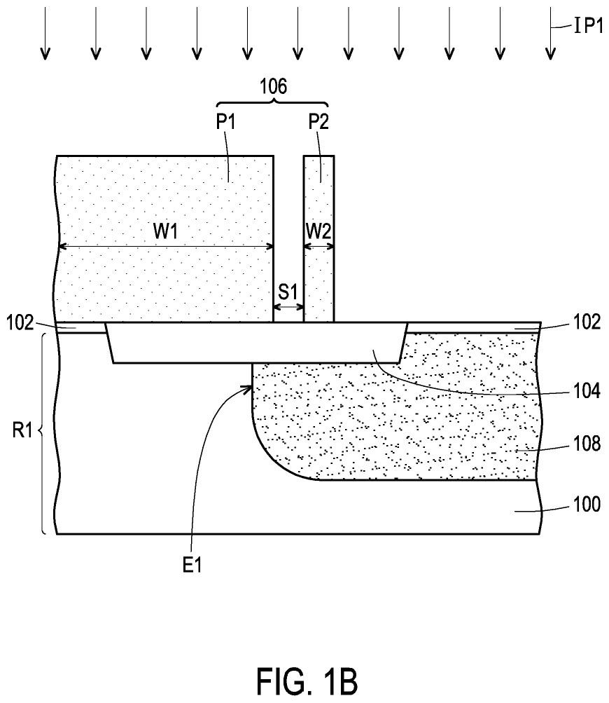

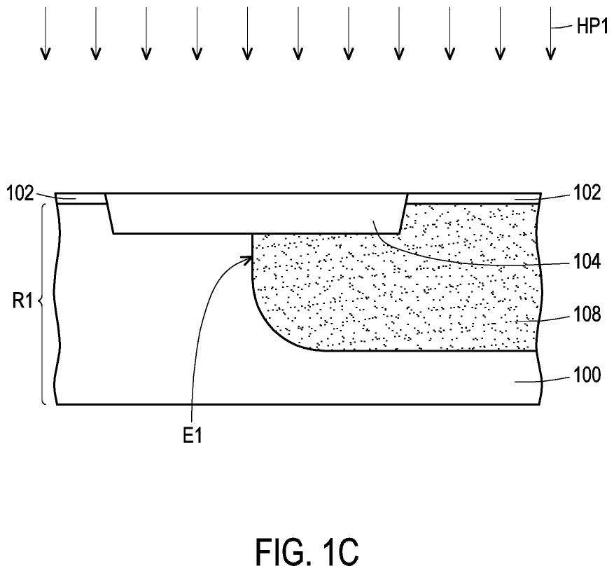

FIG. 1A to FIG. 1C are cross-sectional views of a manufacturing process of a semiconductor structure according to some embodiments of the disclosure.

Referring to FIG. 1A, a substrate 100 is provided. In some embodiments, the substrate 100 may be a semiconductor substrate, such as a silicon substrate. The substrate 100 includes a region R1 of a first conductivity type (e.g., a P-type). In some embodiments, the substrate 100 may have the first conductivity type and be used as the region R1 of the first conductivity type. In some other embodiments, the region R1 of the first conductivity type may be a well region of the first conductivity type formed in the substrate 100. In some embodiments, the substrate 100 may further include other regions as required, and the description thereof is omitted here.

Hereinafter, the first conductivity type and the second conductivity type may be one and another of a P-type conductivity type and an N-type conductivity type, respectively. In this embodiment, the first conductivity type may be the P-type conductivity type, and the second conductivity type may be the N-type conductivity type, but the disclosure is not limited thereto. In some other embodiments, the first conductivity type may be the N-type conductivity type, and the second conductivity type may be the P-type conductivity type.

In some embodiments, a dielectric layer 102 may be formed on the substrate 100, but the disclosure is not limited thereto. In some other embodiments, the dielectric layer 102 may be omitted. In some embodiments, a material of the dielectric layer 102 is, for example, silicon oxide. In some embodiments, a forming method of the dielectric layer 102 is, for example, a thermal oxidation method.

In some embodiments, an isolation structure 104 may be formed in the substrate 100, but the disclosure is not limited thereto. In some other embodiments, the isolation structure 104 may be omitted. In some embodiments, the isolation structure 104 is, for example, a shallow trench isolation (STI) structure. In some embodiments, a material of the isolation structure 104 is, for example, silicon oxide. In some embodiments, the isolation structure 104 may be formed by an STI structure process.

Next, a patterned photoresist layer 106 is formed above the substrate 100. In some embodiments, a part of the patterned photoresist layer 106 may be positioned on the dielectric layer 102. In some embodiments, the patterned photoresist layer 106 may expose a part of the dielectric layer 102. In some embodiments, a part of the patterned photoresist layer 106 may be positioned on the isolation structure 104. In some embodiments, the patterned photoresist layer 106 may expose a part of the isolation structure 104.

The patterned photoresist layer 106 includes a main portion P1 and a split portion P2 separated from each other. The split portion P2 may be a terminal portion of the patterned photoresist layer 106. A width W1 of the main portion P1 may be greater than a width W2 of the split portion P2. In some embodiments, the width W2 of the split portion P2 may be 0.05 μm to 2 μm. In some embodiments, the width W2 of the split portion P2 may be 0.2 μm to 1 μm. In some embodiments, a spacing S1 of the main portion P1 and the split portion P2 may be 0.05 μm to 2 μm. In some embodiments, the spacing S1 of the main portion P1 and the split portion P2 may be 0.2 μm to 1 μm. In this embodiment, one split portion P2 is taken as an example, but the disclosure is not limited thereto. In some other embodiments, the split portion P2 may be multiple. As long as there is at least one split portion P2, it falls within the scope of the disclosure.

Referring to FIG. 1B, an ion implantation process IP1 is performed on the substrate 100 by using the patterned photoresist layer 106 as a mask to form a well region 108 in the region R1 of the first conductivity type. The well region 108 has the second conductivity type (e.g., the N-type). Thereby, a PN junction may be formed between the region R1 of the first conductivity type and the well region 108. In this way, a part of the well region 108 adjacent to an end terminal E1 may have a low doping concentration, so that a depletion region may be enlarged, thereby increasing a breakdown voltage of the PN junction. The main portion P1 and the split portion P2 are adjacent to the same end terminal E1 of the well region 108. In some embodiments, the split portion P2 may be positioned directly above the well region 108. In some embodiments, a part of the well region 108 may be positioned directly under the isolation structure 104.

Referring to FIG. 1C, the patterned photoresist layer 106 may be removed. In some embodiments, a removal method of the patterned photoresist layer 106 is, for example, dry stripping or wet stripping.

Next, a heating process HP1 may be performed on the substrate 100. In some embodiments, after the heating process HP1 is performed, the part of the well region 108 adjacent to the end terminal E1 may still have a low doping concentration. In some embodiments, before the heating process HP1 is performed, the well region 108 may be a continuous structure (as shown in FIG. 1B) or a discontinuous structure. In some embodiments, after the heating process HP1 is performed, the well region 108 may be the continuous structure. In some embodiments, the heating process HP1 is, for example, a anneal process.

Based on the above, in the manufacturing method of the semiconductor structure, the patterned photoresist layer 106 is formed above the substrate 100, and the patterned photoresist layer 106 includes the main portion P1 and the split portion P2 separated from each other. Next, the ion implantation process is performed on the substrate 100 by using the patterned photoresist layer 106 as a mask to form the well region 108 of the second conductivity type in the region R1 of the first conductivity type. Therefore, the part of the well region 108 adjacent to the end terminal E1 may have a low doping concentration, so that the depletion region may be enlarged, thereby increasing the breakdown voltage of the PN junction.

In summary, in the manufacturing method of the semiconductor structure of the embodiments, the ion implantation process is performed on the substrate by using the patterned photoresist layer including the main portion and the split portion separated from each other as a mask to form the well region of the second conductivity type in the region of the first conductivity type. In this way, the part of the well region adjacent to the end terminal may have a low doping concentration, so that the depletion region may be enlarged, thereby increasing the breakdown voltage of the PN junction.

Although the disclosure has been disclosed above with the embodiments, the embodiments are not intended to limit the disclosure. Persons with ordinary knowledge in the technical field may make some changes and modifications without departing from the spirit and scope of the disclosure. The scope of protection of the disclosure should be defined by the appended claims.

What is claimed is:

1. A manufacturing method of a semiconductor structure, comprising:
providing a substrate, wherein the substrate comprises a region of a first conductivity type;
forming a patterned photoresist layer above the substrate, wherein the patterned photoresist layer comprises a main portion and a split portion separated from each other; and
performing an ion implantation process on the substrate by using the patterned photoresist layer as a mask to form a well region in the region of the first conductivity type, wherein the well region has a second conductivity type, and the main portion and the split portion are adjacent to the same end terminal of the well region.

2. The manufacturing method of the semiconductor structure according to claim 1, wherein the first conductivity type is a P-type conductivity type, and the second conductivity type is an N-type conductivity type.

3. The manufacturing method of the semiconductor structure according to claim 1, wherein the first conductivity type is an N-type conductivity type, and the second conductivity type is a P-type conductivity type.

4. The manufacturing method of the semiconductor structure according to claim 1, wherein the split portion is a terminal portion of the patterned photoresist layer.

5. The manufacturing method of the semiconductor structure according to claim 1, wherein the split portion is directly above the well region.

6. The manufacturing method of the semiconductor structure according to claim 1, wherein a width of the main portion is greater than a width of the split portion.

7. The manufacturing method of the semiconductor structure according to claim 1, wherein a width of the split portion is 0.05 μm to 2 μm.

8. The manufacturing method of the semiconductor structure according to claim 1, wherein a width of the split portion is 0.2 μm to 1 μm.

9. The manufacturing method of the semiconductor structure according to claim 1, wherein a spacing between the main portion and the split portion is 0.05 μm to 2 μm.

10. The manufacturing method of the semiconductor structure according to claim 1, wherein a spacing between the main portion and the split portion is 0.2 μm to 1 μm.

11. The manufacturing method of the semiconductor structure according to claim 1, further comprising:
removing the patterned photoresist layer; and
performing a heating process on the substrate.

12. The manufacturing method of the semiconductor structure according to claim 11, wherein the heating process comprises an anneal process.

13. The manufacturing method of the semiconductor structure according to claim 1, further comprising:
forming a dielectric layer on the substrate.

14. The manufacturing method of the semiconductor structure according to claim 13, wherein a part of the patterned photoresist layer is positioned on the dielectric layer.

15. The manufacturing method of the semiconductor structure according to claim 13, wherein the patterned photoresist layer exposes a part of the dielectric layer.

16. The manufacturing method of the semiconductor structure according to claim 13, wherein a forming method of the dielectric layer comprises a thermal oxidation method.

17. The manufacturing method of the semiconductor structure according to claim 1, further comprising:
forming an isolation structure in the substrate.

18. The manufacturing method of the semiconductor structure according to claim 17, wherein a part of the patterned photoresist layer is positioned on the isolation structure.

19. The manufacturing method of the semiconductor structure according to claim 17, wherein the patterned photoresist layer exposes a part of the isolation structure.

20. The manufacturing method of the semiconductor structure according to claim 17, wherein a part of the well region is positioned directly under the isolation structure.
